(19) United States
(12) Patent Application Publication
(10) Pub. No.: US 2026/0282540 A1
(43) Pub. Date: Sep. 17, 2026

(54) SEMICONDUCTOR DEVICE

(71) Applicant: KABUSHIKI KAISHA TOSHIBA, Kawasaki-shi (JP)

(72) Inventors: Po-Chin HUANG, Bunkyo Tokyo (JP); Peitsen WU, Kawasaki Kanagawa (JP)

(73) Assignee: KABUSHIKI KAISHA TOSHIBA, Kawasaki-shi (JP)

(21) Appl. No.: 19/464,895

(22) Filed: Jan. 30, 2026

(30) Foreign Application Priority Data
Mar. 13, 2025 (JP) 2025-040623

(51) Int. Cl. H10D 84/86; H10D 30/47; H10D 62/85

(52) U.S. Cl. CPC H10D 84/86; H10D 30/475; H10D 62/8503

(57) ABSTRACT

According to one embodiment, a semiconductor device includes first to sixth electrodes a semiconductor member, a first insulating member, and a second insulating member. The semiconductor member includes a first semiconductor region including Alₓ₁Ga₁₋ₓ₁N (0<x1≤1), a second semiconductor region including Alₓ₂Ga₁₋ₓ₂N (0≤x2<1, x2<x1), and a third semiconductor region including Alₓ₃Ga₁₋ₓ₃N (0<x3≤1, x2<x3). At least a part of the first insulating member is between the third electrode and the semiconductor member. At least a part of the second insulating member is between the sixth electrode and the semiconductor member. A <0001> direction of the first semiconductor region is along a first orientation from the second semiconductor region to the first semiconductor region.

### CROSS-REFERENCE TO RELATED APPLICATIONS

This application is based upon and claims the benefit of priority from Japanese Patent Application No. 2025-040623, filed on Mar. 13, 2025; the entire contents of which are incorporated herein by reference.

### FIELD

Embodiments described herein relate generally to a semiconductor device.

### BACKGROUND

For example, it is desirable to improve the characteristics of semiconductor devices, such as transistors.

### BRIEF DESCRIPTION OF THE DRAWINGS

FIG. 1 is a schematic cross-sectional view illustrating a semiconductor device according to a first embodiment;

FIG. 2 is a schematic cross-sectional view illustrating a semiconductor device according to the first embodiment;

FIG. 3 is a schematic cross-sectional view illustrating a semiconductor device according to a second embodiment;

FIG. 4 is a schematic cross-sectional view illustrating a semiconductor device according to the second embodiment; and

FIG. 5 is a schematic cross-sectional view illustrating a semiconductor device according to a third embodiment.

### DETAILED DESCRIPTION

According to one embodiment, a semiconductor device includes a first electrode, a second electrode, a third electrode, a fourth electrode, a fifth electrode, a sixth electrode, a semiconductor member, a first insulating member, and a second insulating member. The semiconductor member includes a first semiconductor region including Alₓ₁Ga₁₋ₓ₁N (0<x1≤1), a second semiconductor region including Alₓ₂Ga₁₋ₓ₂N (0≤x2<1, x2<x1), and a third semiconductor region including Alₓ₃Ga₁₋ₓ₃N (0<x3≤1, x2<x3). A direction from the first semiconductor region to the first electrode, the second electrode, the third electrode, the fourth electrode, the fifth electrode, and the sixth electrode is along a first direction. A second direction from the first electrode to the second electrode intersects with the first direction. A third electrode position of the third electrode in the second direction is between a first electrode position of the first electrode in the second direction and a second electrode position of the second electrode in the second direction. The second semiconductor region includes a first partial region, a second partial region, and a third partial region. The first partial region is between the first semiconductor region and the first electrode in the first direction. The second partial region is between the first semiconductor region and the second electrode in the first direction. The third partial region is between the first semiconductor region and the third electrode in the first direction. The third semiconductor region includes a first semiconductor portion and a second semiconductor portion. The first semiconductor portion is between the first partial region and the first electrode. The second semiconductor portion is between the second partial region and the second electrode. At least a part of the third electrode is between the first semiconductor portion and the second semiconductor portion in the second direction. At least a part of the first insulating member is between the third electrode and the semiconductor member. A third direction from the fourth electrode to the fifth electrode intersects with the first direction. A sixth electrode position of the sixth electrode in the third direction is between a fourth electrode position of the fourth electrode in the third direction and a fifth electrode position of the fifth electrode in the third direction. The second semiconductor region further includes a fourth partial region, a fifth partial region, and a sixth partial region. The fourth partial region is between the first semiconductor region and the fourth electrode in the first direction. The fifth partial region is between the first semiconductor region and the fifth electrode in the first direction. The sixth partial region is between the first semiconductor region and the sixth electrode in the first direction. At least a part of the sixth electrode is between the fourth partial region and the fifth partial region in the third direction. At least a part of the second insulating member is between the sixth electrode and the semiconductor member. A <0001> direction of the first semiconductor region is along a first orientation from the second semiconductor region to the first semiconductor region.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

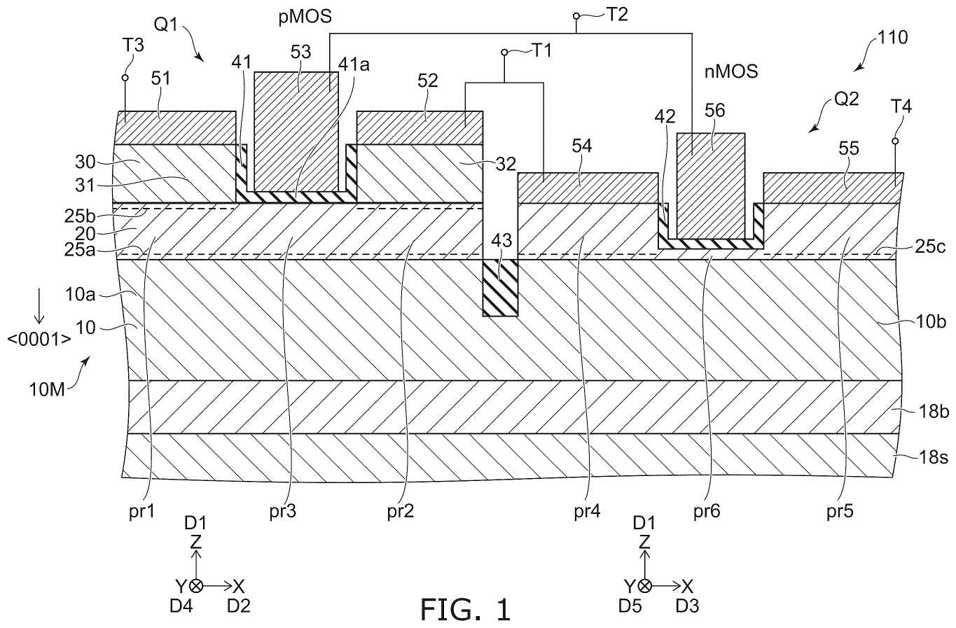

FIG. 1 is a schematic cross-sectional view illustrating a semiconductor device according to a first embodiment.

As shown in FIG. 1, a semiconductor device 110 according to the embodiment includes a first electrode 51, a second electrode 52, a third electrode 53, a fourth electrode 54, a fifth electrode 55, a sixth electrode 56, a semiconductor member 10M, a first insulating member 41, and a second insulating member 42.

The semiconductor member 10M includes a crystal. The semiconductor member 10M includes a first semiconductor region 10, a second semiconductor region 20, and a third semiconductor region 30. The first semiconductor region 10 includes Alₓ₁Ga₁₋ₓ₁N (0<x1≤1). The composition ratio x1 may be, for example, 0.9 or more and 1 or less. The first semiconductor region 10 may include AlN.

The second semiconductor region 20 includes Alₓ₂Ga₁₋ₓ₂N (0≤x2<1, x2<x1). The composition ratio x2 may be, for example, 0 or more and less than 0.15. The second semiconductor region 20 may include GaN or AlGaN.

The third semiconductor region 30 includes Alₓ₃Ga₁₋ₓ₃N (0<x3≤1, x2<x3). The composition ratio x3 may be, for example, 0.15 or more and 1 or less. The composition ratio x3 may be lower than the composition ratio x1.

A direction from the first semiconductor region 10 to the first electrode 51, the second electrode 52, the third electrode 53, the fourth electrode 54, the fifth electrode 55, and the sixth electrode 56 is along a first direction D1.

The first direction D1 is defined as a Z-axis direction. One direction perpendicular to the Z-axis direction is defined as an X-axis direction. A direction perpendicular to the Z-axis direction and the X-axis direction is defined as a Y-axis direction. The first semiconductor region 10 is, for example, along the X-Y plane.

A second direction D2 from the first electrode 51 to the second electrode 52 intersects with the first direction D1. The second direction D2 may be, for example, the X-axis direction.

The position (third electrode position) of the third electrode 53 in the second direction D2 is between the position (first electrode position) of the first electrode 51 in the second direction D2 and the position (second electrode position) of the second electrode 52 in the second direction D2.

The second semiconductor region 20 includes a first partial region pr1, a second partial region pr2, and a third partial region pr3. The first partial region pr1 is between the first semiconductor region 10 and the first electrode 51 in the first direction D1. The second partial region pr2 is between the first semiconductor region 10 and the second electrode 52 in the first direction D1. The third partial region pr3 is between the first semiconductor region 10 and the third electrode 53 in the first direction D1.

The third semiconductor region 30 includes a first semiconductor portion 31 and a second semiconductor portion 32. The first semiconductor portion 31 is between the first partial region pr1 and the first electrode 51. The second semiconductor portion 32 is between the second partial region pr2 and the second electrode 52.

At least a part of the third electrode 53 is between the first semiconductor portion 31 and the second semiconductor portion 32 in the second direction D2. At least a part of the first insulating member 41 is between the third electrode 53 and the semiconductor member 10M.

A third direction D3 from the fourth electrode 54 to the fifth electrode 55 intersects with the first direction D1. In this example, the third direction D3 is along the second direction D2. The third direction D3 may intersect with the second direction D2.

The position (sixth electrode position) of the sixth electrode 56 in the third direction D3 is between the position (fourth electrode position) of the fourth electrode 54 in the third direction D3 and the position (fifth electrode position) of the fifth electrode 55 in the third direction D3.

The second semiconductor region 20 further includes a fourth partial region pr4, a fifth partial region pr5, and a sixth partial region pr6. The fourth partial region pr4 is between the first semiconductor region 10 and the fourth electrode 54 in the first direction D1. The fifth partial region pr5 is between the first semiconductor region 10 and the fifth electrode 55 in the first direction D1. The sixth partial region pr6 is between the first semiconductor region 10 and the sixth electrode 56 in the first direction D1.

At least a part of the sixth electrode 56 is between the fourth partial region pr4 and the fifth partial region pr5 in the third direction D3. At least a part of the second insulating member 42 is between the sixth electrode 56 and the semiconductor member 10M.

The <0001> direction of the first semiconductor region 10 is along a first orientation from the second semiconductor region 20 to the first semiconductor region 10. The first semiconductor region 10 is, for example, an N-polar layer.

A first current flowing between the first electrode 51 and the second electrode 52 is controlled by a first potential of the third electrode 53. The first potential may be a potential based on the potential of the first electrode 51. The first electrode 51 functions as, for example, a source electrode. The second electrode 52 functions as, for example, a drain electrode. The third electrode 53 functions as, for example, a gate electrode.

A first transistor Q1 including the first electrode 51, the second electrode 52, the third electrode 53, and the third semiconductor region 30 functions as one transistor.

A second current flowing between the fourth electrode 54 and the fifth electrode 55 is controlled by a second potential of the sixth electrode 56. The second potential may be a potential based on the potential of the fifth electrode 55. The fourth electrode 54 functions as, for example, another drain electrode. The fifth electrode 55 functions as, for example, another source electrode. The sixth electrode 56 functions as, for example, another gate electrode.

A second transistor Q2 including the fourth electrode 54, the fifth electrode 55, the sixth electrode 56, the fourth partial region pr4, the fifth partial region pr5, and the sixth partial region pr6 functions as another transistor.

The first transistor Q1 functions as, for example, a p-MOS transistor. The second transistor Q2 functions as, for example, an n-MOS transistor.

The first partial region pr1, the second partial region pr2, and the third partial region pr3 include a portion facing the first semiconductor region 10. In one example, a first carrier region 25a is formed in this portion. The first partial region pr1 and the second partial region pr2 include a portion facing the third semiconductor region 30. A second carrier region 25b is formed in this portion. The first carrier region 25a may be a two-dimensional electron gas. The second carrier region 25b may be a two-dimensional hole gas.

The fourth partial region pr4 and the fifth partial region pr5 include a portion facing the first semiconductor region 10. In one example, a third carrier region 25c is formed in this portion. The third carrier region 25c may be, for example, a two-dimensional electron gas. The first transistor Q1 and the second transistor Q2 are, for example, HEMTs (High-Electron-Mobility Transistors).

A high threshold voltage is obtained in the first transistor Q1. This is based on the configuration of the three semiconductor regions having different Al composition ratios. The first transistor Q1 need not include, for example, a p-type semiconductor layer. Since impurities need not be introduced, high crystallinity is obtained. For example, a high mobility is obtained. For example, a low on-resistance is obtained. According to the embodiment, a semiconductor device capable of improving characteristics can be provided.

In the embodiment, the p-MOS transistor and the n-MOS transistor may be combined to obtain a CMOS configuration. According to the embodiment, the p-MOS transistor and the n-MOS transistor are obtained with a simple configuration. For example, the p-MOS transistor and the n-MOS transistor are obtained by a simple process.

For example, a first terminal T1, a second terminal T2, a third terminal T3, and a fourth terminal T4 may be provided. The first terminal T1 is electrically connected to the second electrode 52 and the fourth electrode 54. The second terminal T2 is electrically connected to the third electrode 53 and the sixth electrode 56. The third terminal T3 is electrically connected to the first electrode 51. The fourth terminal T4 is electrically connected to the fifth electrode 55.

The fourth terminal T4 is set to, for example, the ground potential. For example, a supply voltage is applied to the third terminal T3. For example, an input voltage is applied to the second terminal T2. For example, an output voltage is obtained from the first terminal T1.

For example, when one of the first transistor Q1 and the second transistor Q2 is in the ON state, the other of the first transistor Q1 and the second transistor Q2 may be in the OFF state.

For example, the first transistor Q1 is configured to perform a normally-off operation. The second transistor Q2 may be configured to perform a normally-off operation.

In the semiconductor device 110, the <0001> direction of the second semiconductor region 20 is along the first orientation described above. The <0001> direction of the third semiconductor region 30 is along the first orientation described above.

For example, the first semiconductor region 10 is in contact with the second semiconductor region 20. For example, the second semiconductor region 20 (the first partial region pr1, the second partial region pr2, and the third partial region pr3) is in contact with the third semiconductor region 30.

The fourth electrode 54 may be in contact with the fourth partial region pr4. The fifth electrode 55 may be in contact with the fifth partial region pr5. The fourth electrode 54 is electrically connected to the fourth partial region pr4. The fifth electrode 55 is electrically connected to the fifth partial region pr5.

The first electrode 51 is electrically connected to the first semiconductor portion 31. The second electrode 52 is electrically connected to the second semiconductor portion 32.

As shown in FIG. 1, the first insulating member 41 includes a first insulating region 41a. The first insulating region 41a is between the third partial region pr3 and the third electrode 53. In this example, the first insulating region 41a is in contact with the third partial region pr3 and the third electrode 53.

In this example, the semiconductor device 110 includes a base 18s. The semiconductor device 110 may include a nitride layer 18b. The semiconductor member 10M is provided between the base 18s and the electrodes. The nitride layer 18b is provided between the base 18s and the semiconductor member 10M. The base 18s may include, for example, at least one selected from the group consisting of Si, SiC, and sapphire. The nitride layer 18b may include, for example, Al and N. The nitride layer 18b may include any buffer layer.

As shown in FIG. 1, the first semiconductor region 10 includes a first region 10a and a second region 10b. The first partial region pr1 is between the first region 10a and the first electrode 51 in the first direction D1. The second partial region pr2 is between the first region 10a and the second electrode 52 in the first direction D1. The third partial region pr3 is between the first region 10a and the third electrode 53 in the first direction D1. In the example shown in FIG. 1, the thickness of the first partial region pr1 in the first direction D1, the thickness of the second partial region pr2 in the first direction D1, and the thickness of the third partial region pr3 in the first direction D1 are the same.

The fourth partial region pr4 is between the second region 10b and the fourth electrode 54 in the first direction D1. The fifth partial region pr5 is between the second region 10b and the fifth electrode 55 in the first direction D1. The sixth partial region pr6 is between the second region 10b and the sixth electrode 56 in the first direction D1. In the example shown in FIG. 1, the thickness of the sixth partial region pr6 in the first direction D1 is smaller than the thickness of the fourth partial region pr4 in the first direction D1. In the example shown in FIG. 1, the thickness of the sixth partial region pr6 in the first direction D1 is smaller than the thickness of the third partial region pr3 in the first direction D1. The thickness of the sixth partial region pr6 in the first direction D1 may be, for example, more than 0 nm and 5 nm or less. A stable operation is obtained in the second transistor Q2 including the sixth partial region pr6. The thickness of the sixth partial region pr6 in the first direction D1 may be, for example, 0 nm or more and 5 nm or less.

As shown in FIG. 1, the first semiconductor region 10 may include a first intermediate region 43. The first intermediate region 43 is between the first region 10a and the second region 10b. The electric resistance (first intermediate region electric resistance) of the first intermediate region 43 is higher than a first electric resistance of the first region 10a and higher than a second electric resistance of the second region 10b. The first transistor Q1 and the second transistor Q2 are electrically separated from each other.

The first intermediate region 43 may include a material included in the first region 10a and the second region 10b. For example, ions or the like are implanted into a part of a semiconductor layer that serves as the first semiconductor region 10. This results in a high electric resistance. The first intermediate region 43 may include an insulating material, such as silicon oxide.

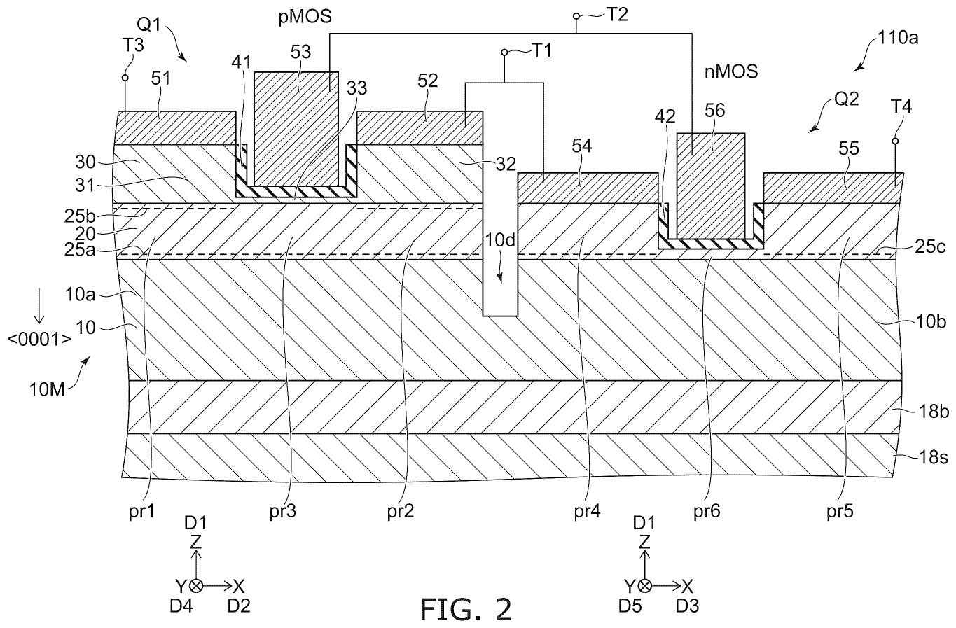

FIG. 2 is a schematic cross-sectional view illustrating a semiconductor device according to the first embodiment.

As shown in FIG. 2, in a semiconductor device 110a according to the embodiment, the third semiconductor region 30 further includes a third semiconductor portion 33. The configuration of the semiconductor device 110a may be otherwise similar to the configuration of the semiconductor device 110.

The third semiconductor portion 33 is between the third partial region pr3 and the third electrode 53 in the first direction D1. A part of the first insulating member 41 is between the third semiconductor portion 33 and the third electrode 53. Also in the semiconductor device 110a, a high threshold voltage is obtained in the first transistor Q1.

The thickness of the third semiconductor portion 33 in the first direction D1 is more than 0 nm and 5 nm or less. A stable operation is obtained in the first transistor Q1 including the third partial region pr3.

As shown in FIG. 2, the first semiconductor region 10 includes the first region 10a and the second region 10b. In this example, the first semiconductor region 10 includes a recessed portion 10d between the first region 10a and the second region 10b. The thickness of a region (recessed portion 10d) between the first region 10a and the second region 10b in the first direction D1 is smaller than the thickness of the first region 10a in the first direction D1. The thickness of the region (recessed portion 10d) between the first region 10a and the second region 10b in the first direction D1 is smaller than the thickness of the second region 10b in the first direction D1. The first transistor Q1 and the second transistor Q2 are electrically separated from each other by the recessed portion 10d. In the semiconductor device 110a, the first intermediate region 43 having a high electric resistance may be provided.

### Second Embodiment

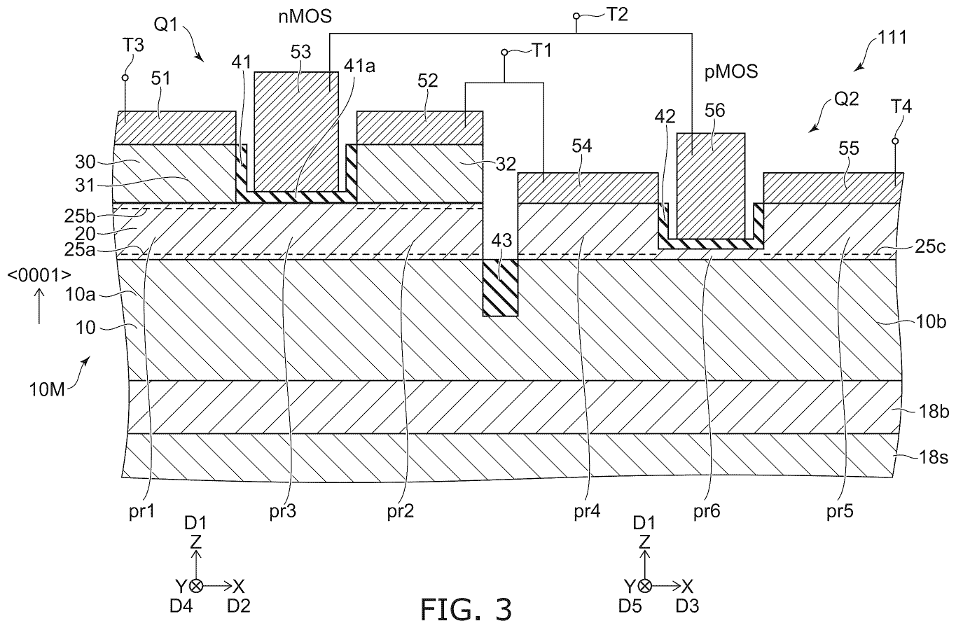

FIG. 3 is a schematic cross-sectional view illustrating a semiconductor device according to a second embodiment.

As shown in FIG. 3, a semiconductor device 111 according to the embodiment includes the first electrode 51, the second electrode 52, the third electrode 53, the fourth electrode 54, the fifth electrode 55, the sixth electrode 56, the semiconductor member 10M, the first insulating member 41, and the second insulating member 42. The crystal orientation in the semiconductor device 111 is different from the crystal orientation in the semiconductor device 110. The configuration of the semiconductor device 111 may be otherwise similar to the configuration of the semiconductor device 110.

In the semiconductor device 111, the <0001> direction of the first semiconductor region 10 is along a second orientation from the first semiconductor region 10 to the second semiconductor region 20. The first semiconductor region 10 is, for example, an Al-polar layer. Alternatively, the first semiconductor region 10 is, for example, a Ga-polar layer.

The first current flowing between the first electrode 51 and the second electrode 52 is controlled by the first potential of the third electrode 53. The second current flowing between the fourth electrode 54 and the fifth electrode 55 is controlled by the second potential of the sixth electrode 56.

For example, the first transistor Q1 including the first electrode 51, the second electrode 52, the third electrode 53, and the third semiconductor region 30 is configured to perform a normally-off operation. The second transistor Q2 including the fourth electrode 54, the fifth electrode 55, the sixth electrode 56, the fourth partial region pr4, the fifth partial region pr5, and the sixth partial region pr6 is configured to perform a normally-off operation.

The first transistor Q1 functions as, for example, an n-MOS transistor. The second transistor Q2 functions as, for example, a p-MOS transistor.

The first partial region pr1, the second partial region pr2, and the third partial region pr3 include a portion facing the first semiconductor region 10. In one example, the first carrier region 25a is formed in this portion. The first partial region pr1 and the second partial region pr2 include a portion facing the third semiconductor region 30. The second carrier region 25b is formed in this portion. The first carrier region 25a may be a two-dimensional hole gas. The second carrier region 25b may be a two-dimensional electron gas.

The fourth partial region pr4 and the fifth partial region pr5 include a portion facing the first semiconductor region 10. In one example, the third carrier region 25c is formed in this portion. The third carrier region 25c may be, for example, a two-dimensional hole gas.

In the semiconductor device 111, the <0001> direction of the second semiconductor region 20 is along the second orientation described above. The <0001> direction of the third semiconductor region 30 is along the second orientation described above.

For example, the fourth electrode 54 may be in contact with the fourth partial region pr4. The fifth electrode 55 may be in contact with the fifth partial region pr5. The fourth electrode 54 is electrically connected to the fourth partial region pr4. The fifth electrode 55 is electrically connected to the fifth partial region pr5.

In the semiconductor device 111, the first insulating member 41 includes the first insulating region 41a between the third partial region pr3 and the third electrode 53. The first insulating region 41a is in contact with the third partial region pr3 and the third electrode 53.

In the example of the semiconductor device 111, the first semiconductor region 10 includes the first intermediate region 43. The electric resistance (first intermediate region electric resistance) of the first intermediate region 43 is higher than the first electric resistance of the first region 10a and higher than the second electric resistance of the second region 10b. The first transistor Q1 and the second transistor Q2 are electrically separated from each other.

In the example of the semiconductor device 111, the thickness of the sixth partial region pr6 in the first direction D1 may be, for example, more than 0 nm and 5 nm or less. In the example of the semiconductor device 111, the thickness of the sixth partial region pr6 in the first direction D1 may be, for example, 0 nm or more and 5 nm or less.

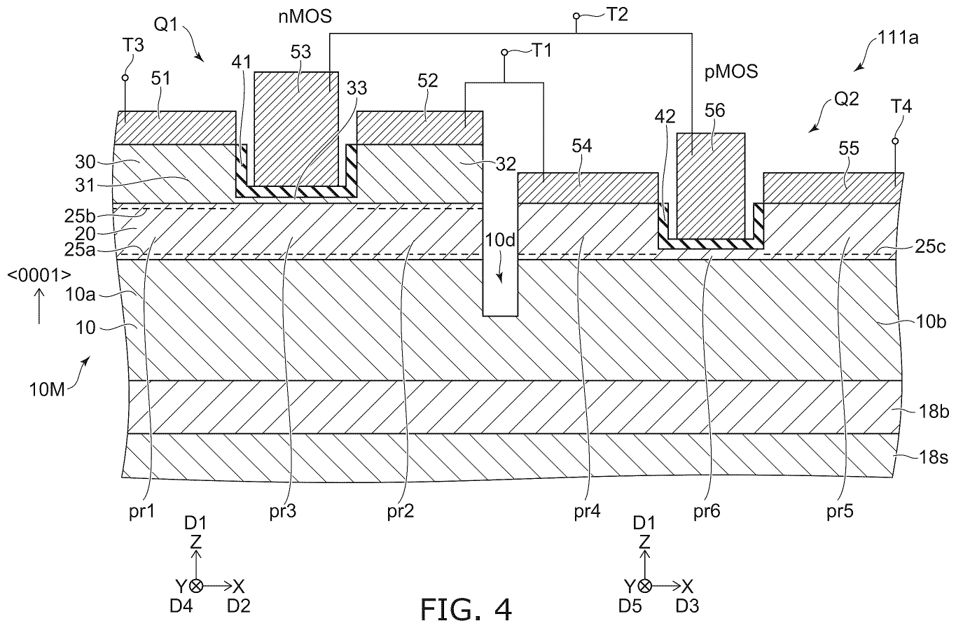

FIG. 4 is a schematic cross-sectional view illustrating a semiconductor device according to the second embodiment.

As shown in FIG. 4, in a semiconductor device 111a according to the embodiment, the third semiconductor region 30 further includes the third semiconductor portion 33. The configuration of the semiconductor device 111a may be otherwise similar to the configuration of the semiconductor device 111.

The third semiconductor portion 33 is between the third partial region pr3 and the third electrode 53 in the first direction D1. A part of the first insulating member 41 is between the third semiconductor portion 33 and the third electrode 53.

The thickness of the third semiconductor portion 33 in the first direction D1 is more than 0 nm and 5 nm or less. A stable operation is obtained in the first transistor Q1 including the third semiconductor portion 33.

As shown in FIG. 4, the first semiconductor region 10 includes the first region 10a and the second region 10b. In this example, the first semiconductor region 10 includes the recessed portion 10d between the first region 10a and the second region 10b. The first transistor Q1 and the second transistor Q2 are electrically separated from each other by the recessed portion 10d. In the semiconductor device 111a, the first intermediate region 43 having a high electric resistance may be provided.

### Third Embodiment

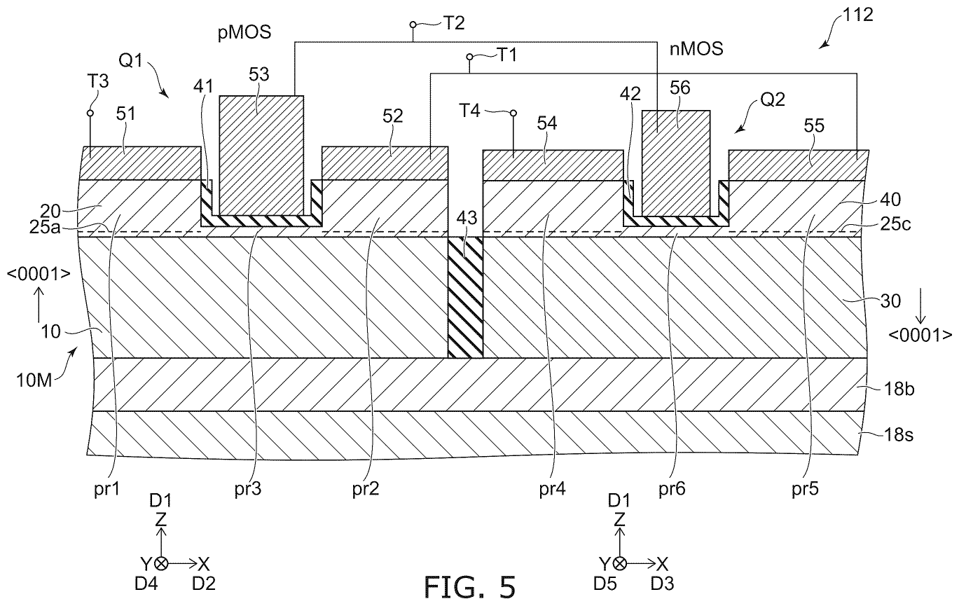

FIG. 5 is a schematic cross-sectional view illustrating a semiconductor device according to a third embodiment.

As shown in FIG. 5, the configuration of the semiconductor member 10M in the semiconductor device 112 according to the embodiment is different from the configuration of the semiconductor member 10M in the semiconductor device according to the first embodiment or the second embodiment. The configuration of the semiconductor device 112 may be otherwise similar to the configuration of the semiconductor device according to the first embodiment or the second embodiment.

The semiconductor device 112 according to the embodiment includes the first electrode 51, the second electrode 52, the third electrode 53, the fourth electrode 54, the fifth electrode 55, the sixth electrode 56, the semiconductor member 10M, the first insulating member 41, and the second insulating member 42.

The semiconductor member 10M includes the first semiconductor region 10, the second semiconductor region 20, the third semiconductor region 30, and a fourth semiconductor region 40.

The first semiconductor region 10 includes Alₓ₁Ga₁₋ₓ₁N (0<x1≤1). The composition ratio x1 may be, for example, 0.9 or more and 1 or less. The first semiconductor region 10 may include, for example, AlN.

The second semiconductor region 20 includes Alₓ₂Ga₁₋ₓ₂N (0≤x2<1, x2<x1). The composition ratio x2 may be, for example, 0 or more and 0.2 or less. The second semiconductor region 20 may include, for example, GaN or AlGaN.

The third semiconductor region 30 includes Alₓ₃Ga₁₋ₓ₃N (0<x3≤1). The composition ratio x3 may be, for example, 0.9 or more and 1 or less. The third semiconductor region 30 may include, for example, AlN.

The fourth semiconductor region 40 includes Alₓ₄Ga₁₋ₓ₄N (0≤x4<1, x4<x3). The composition ratio x4 may be, for example, 0 or more and 0.2 or less. The fourth semiconductor region 40 may include, for example, GaN or AlGaN.

A direction from the first semiconductor region 10 to the first electrode 51, the second electrode 52, and the third electrode 53 is along the first direction D1. The second direction D2 from the first electrode 51 to the second electrode 52 intersects with the first direction D1. The third electrode position of the third electrode 53 in the second direction D2 is between the first electrode position of the first electrode 51 in the second direction D2 and the second electrode position of the second electrode 52 in the second direction D2.

The second semiconductor region 20 includes the first partial region pr1 and the second partial region pr2. The first partial region pr1 is between the first semiconductor region 10 and the first electrode 51 in the first direction D1. The second partial region pr2 is between the first semiconductor region 10 and the second electrode 52 in the first direction D1.

At least a part of the third electrode 53 is between the first partial region pr1 and the second partial region pr2 in the second direction D2.

The <0001> direction of the first semiconductor region 10 is along the first orientation from the first semiconductor region 10 to the second semiconductor region 20. The first semiconductor region 10 is, for example, an Al-polar layer (or a Ga-polar layer).

At least a part of the first insulating member 41 is between the third electrode 53 and the semiconductor member 10M.

A direction from the third semiconductor region 30 to the fourth electrode 54, the fifth electrode 55, and the sixth electrode 56 is along the first direction D1. The third direction D3 from the fourth electrode 54 to the fifth electrode 55 intersects with the first direction D1. The sixth electrode position of the sixth electrode 56 in the third direction D3 is between the fourth electrode position of the fourth electrode 54 in the third direction D3 and the fifth electrode position of the fifth electrode 55 in the third direction D3.

The fourth semiconductor region 40 includes the fourth partial region pr4 and the fifth partial region pr5. The fourth partial region pr4 is between the third semiconductor region 30 and the fourth electrode 54 in the first direction D1. The fifth partial region pr5 is between the third semiconductor region 30 and the fifth electrode 55 in the first direction D1.

At least a part of the sixth electrode 56 is between the fourth partial region pr4 and the fifth partial region pr5 in the third direction D3.

The <0001> direction of the third semiconductor region 30 is along the second orientation from the fourth semiconductor region 40 to the third semiconductor region 30. The third semiconductor region 30 is, for example, an N-polar layer.

At least a part of the second insulating member 42 is between the sixth electrode 56 and the semiconductor member 10M.

The first current flowing between the first electrode 51 and the second electrode 52 is controlled by the first potential of the third electrode 53. The first potential may be a potential based on the potential of the first electrode 51. The first electrode 51 functions as, for example, a source electrode. The second electrode 52 functions as, for example, a drain electrode. The third electrode 53 functions as, for example, a gate electrode.

The first transistor Q1 including the first electrode 51, the second electrode 52, the third electrode 53, the first partial region pr1, and the second partial region pr2 functions as one transistor.

The second current flowing between the fourth electrode 54 and the fifth electrode 55 is controlled by the second potential of the sixth electrode 56. The second potential may be a potential based on the potential of the fifth electrode 55. The fourth electrode 54 functions as, for example, another source electrode. The fifth electrode 55 functions as, for example, another drain electrode. The sixth electrode 56 functions as, for example, another gate electrode.

The second transistor Q2 including the fourth electrode 54, the fifth electrode 55, the sixth electrode 56, the fifth partial region pr5, and the fourth partial region pr4 functions as another transistor.

For example, the first transistor Q1 is configured to perform a normally-off operation. The second transistor Q2 may be configured to perform a normally-off operation.

The first transistor Q1 functions as, for example, a p-MOS transistor. The second transistor Q2 functions as, for example, an n-MOS transistor.

The first partial region pr1 and the second partial region pr2 include a portion facing the first semiconductor region 10. In one example, the first carrier region 25a is formed in this portion. The first carrier region 25a may be a two-dimensional hole gas.

The fourth partial region pr4 and the fifth partial region pr5 include a portion facing the third semiconductor region 30. In one example, the third carrier region 25c is formed in this portion. The third carrier region 25c may be, for example, a two-dimensional electron gas. The first transistor Q1 and the second transistor Q2 are, for example, HEMTs.

The p-MOS transistor and the n-MOS transistor may be combined to obtain a CMOS configuration.

For example, the first terminal T1, the second terminal T2, the third terminal T3, and the fourth terminal T4 may be provided. The first terminal T1 is electrically connected to the second electrode 52 and the fifth electrode 55. The second terminal T2 is electrically connected to the third electrode 53 and the sixth electrode 56. The third terminal T3 is electrically connected to the first electrode 51. The fourth terminal T4 is electrically connected to the fourth electrode 54.

The fourth terminal T4 is set to, for example, the ground potential. For example, a supply voltage is applied to the third terminal T3. For example, an input voltage is applied to the second terminal T2. For example, an output voltage is obtained from the first terminal T1.

In the semiconductor device 112, the <0001> direction of the second semiconductor region 20 is along the first orientation from the first semiconductor region 10 to the second semiconductor region 20. The <0001> direction of the fourth semiconductor region 40 is along the second orientation from the fourth semiconductor region 40 to the third semiconductor region 30.

The first electrode 51 may be in contact with the first partial region pr1. The second electrode 52 may be in contact with the second partial region pr2. The first electrode 51 is electrically connected to the first partial region pr1. The second electrode 52 is electrically connected to the second partial region pr2.

The fourth electrode 54 may be in contact with the fourth partial region pr4. The fifth electrode 55 may be in contact with the fifth partial region pr5. The fourth electrode 54 is electrically connected to the fourth partial region pr4. The fifth electrode 55 is electrically connected to the fifth partial region pr5.

The second semiconductor region 20 may further include the third partial region pr3. The third partial region pr3 is between the first semiconductor region 10 and the third electrode 53 in the first direction D1. A part of the first insulating member 41 is between the third partial region pr3 and the third electrode 53.

The fourth semiconductor region 40 may further include the sixth partial region pr6. The sixth partial region pr6 is between the third semiconductor region 30 and the sixth electrode 56 in the first direction D1. A part of the second insulating member 42 is between the sixth partial region pr6 and the sixth electrode 56. The thickness of the sixth partial region pr6 in the first direction D1 may be, for example, more than 0 nm and 5 nm or less.

In the first to third embodiments, at least any of the first insulating member 41 and the second insulating member 42 may include oxygen and a first element. The first element includes at least one selected from the group consisting of Si, Al, and Hf. High insulation properties are stably obtained.

At least any of the first insulating member 41 and the second insulating member 42 may include oxygen, nitrogen, and a first element. The first element includes at least one selected from the group consisting of Si and Al.

In the first to third embodiments, the first semiconductor region 10 does not include a p-type impurity. Alternatively, the concentration of the p-type impurity in the first semiconductor region 10 is, for example, less than 1×10¹⁷ cm⁻³. High crystallinity is obtained. A high mobility is obtained. The p-type impurity includes, for example, at least one selected from the group consisting of Mg, Zn, and Be.

In the third embodiment, the third semiconductor region 30 does not include a p-type impurity. Alternatively, the concentration of the p-type impurity in the third semiconductor region 30 is, for example, less than 1×10¹⁷ cm⁻³. High crystallinity is obtained. A high mobility is obtained. The p-type impurity includes, for example, at least one selected from the group consisting of Mg, Zn, and Be.

In the first to third embodiments, the electrodes may include, for example, at least one selected from the group consisting of Al, Ag, Au, Cu, Ti, and Ni.

In the first to third embodiments, the first electrode 51, the second electrode 52, and the third electrode 53 may extend along a fourth direction D4. The fourth direction D4 intersects with a plane that includes the first direction D1 and the second direction D2. The fourth direction D4 may be, for example, the Y-axis direction. The fourth electrode 54, the fifth electrode 55, and the sixth electrode 56 may extend along a fifth direction D5. The fifth direction D5 intersects with a plane that includes the first direction D1 and the third direction D3. The fifth direction D5 may be, for example, the Y-axis direction.

The N-polar layer may be obtained, for example, by treating an underlying layer with an oxygen-containing treatment agent. The various semiconductor regions described above may be obtained by, for example, selective growth. The various semiconductor regions described above may be obtained by, for example, selective removal of a grown film.

In the embodiments, information regarding, for example, the shapes of the semiconductor regions are obtained by, for example, electron microscope observation. Information regarding the compositions and the element concentrations in the semiconductor regions is obtained by, for example, EDX (Energy Dispersive X-ray Spectroscopy) or SIMS (Secondary Ion Mass Spectrometry). The information regarding the compositions in the semiconductor regions may be obtained by, for example, reciprocal space mapping.

The embodiments may include the following technical proposals.

### (Technical Proposal 1)

A semiconductor device comprising:
a first electrode;
a second electrode;
a third electrode;
a fourth electrode;
a fifth electrode;
a sixth electrode;
a semiconductor member;
a first insulating member; and
a second insulating member,
the semiconductor member including
   a first semiconductor region including Alₓ₁Ga₁₋ₓ₁N (0<x1≤1),
   a second semiconductor region including Alₓ₂Ga₁₋ₓ₂N (0≤x2<1, x2<x1), and
   a third semiconductor region including Alₓ₃Ga₁₋ₓ₃N (0<x3≤1, x2<x3),
a direction from the first semiconductor region to the first electrode, the second electrode, the third electrode, the fourth electrode, the fifth electrode, and the sixth electrode being along a first direction,
a second direction from the first electrode to the second electrode intersecting with the first direction,
a third electrode position of the third electrode in the second direction being between a first electrode position of the first electrode in the second direction and a second electrode position of the second electrode in the second direction,
the second semiconductor region including a first partial region, a second partial region, and a third partial region,
the first partial region being between the first semiconductor region and the first electrode in the first direction,
the second partial region being between the first semiconductor region and the second electrode in the first direction,
the third partial region being between the first semiconductor region and the third electrode in the first direction,
the third semiconductor region including a first semiconductor portion and a second semiconductor portion,
the first semiconductor portion being between the first partial region and the first electrode,
the second semiconductor portion being between the second partial region and the second electrode,
at least a part of the third electrode being between the first semiconductor portion and the second semiconductor portion in the second direction,
at least a part of the first insulating member being between the third electrode and the semiconductor member,
a third direction from the fourth electrode to the fifth electrode intersecting with the first direction,
a sixth electrode position of the sixth electrode in the third direction being between a fourth electrode position of the fourth electrode in the third direction and a fifth electrode position of the fifth electrode in the third direction,
the second semiconductor region further including a fourth partial region, a fifth partial region, and a sixth partial region,
the fourth partial region being between the first semiconductor region and the fourth electrode in the first direction,
the fifth partial region being between the first semiconductor region and the fifth electrode in the first direction,
the sixth partial region being between the first semiconductor region and the sixth electrode in the first direction,
at least a part of the sixth electrode being between the fourth partial region and the fifth partial region in the third direction,
at least a part of the second insulating member being between the sixth electrode and the semiconductor member,
a <0001> direction of the first semiconductor region being along a first orientation from the second semiconductor region to the first semiconductor region.

### (Technical Proposal 2)

The semiconductor device according to Technical proposal 1, wherein
a <0001> direction of the second semiconductor region is along the first orientation, and
a <0001> direction of the third semiconductor region is along the first orientation.

### (Technical Proposal 3)

The semiconductor device according to Technical proposal 1 or 2, wherein
the fourth electrode is in contact with the fourth partial region, and
the fifth electrode is in contact with the fifth partial region.

### (Technical Proposal 4)

The semiconductor device according to any one of Technical proposals 1 to 3, wherein
a first current flowing between the first electrode and the second electrode is controlled by a first potential of the third electrode, and
a second current flowing between the fourth electrode and the fifth electrode is controlled by a second potential of the sixth electrode.

### (Technical Proposal 5)

The semiconductor device according to any one of Technical proposals 1 to 4, wherein
a first transistor including the first electrode, the second electrode, the third electrode, and the third semiconductor region is configured to perform a normally-off operation, and
a second transistor including the fourth electrode, the fifth electrode, the sixth electrode, the fourth partial region, the fifth partial region, and the sixth partial region is configured to perform a normally-off operation.

### (Technical Proposal 6)

A semiconductor device comprising:
a first electrode;
a second electrode;
a third electrode;
a fourth electrode;
a fifth electrode;
a sixth electrode;
a semiconductor member;
a first insulating member; and
a second insulating member,
the semiconductor member including
   a first semiconductor region including Alₓ₁Ga₁₋ₓ₁N (0<x1≤1),
   a second semiconductor region including Alₓ₂Ga₁₋ₓ₂N (0≤x2<1, x2<x1), and
   a third semiconductor region including Alₓ₃Ga₁₋ₓ₃N (0<x3≤1, x2<x3),
a direction from the first semiconductor region to the first electrode, the second electrode, the third electrode, the fourth electrode, the fifth electrode, and the sixth electrode being along a first direction,
a second direction from the first electrode to the second electrode intersecting with the first direction,
a third electrode position of the third electrode in the second direction being between a first electrode position of the first electrode in the second direction and a second electrode position of the second electrode in the second direction,
the second semiconductor region including a first partial region, a second partial region, and a third partial region,
the first partial region being between the first semiconductor region and the first electrode in the first direction,
the second partial region being between the first semiconductor region and the second electrode in the first direction,
the third partial region being between the first semiconductor region and the third electrode in the first direction,
the third semiconductor region including a first semiconductor portion and a second semiconductor portion,
the first semiconductor portion being between the first partial region and the first electrode,
the second semiconductor portion being between the second partial region and the second electrode,
at least a part of the third electrode being between the first semiconductor portion and the second semiconductor portion in the second direction,
at least a part of the first insulating member being between the third electrode and the semiconductor member,
a third direction from the fourth electrode to the fifth electrode intersecting with the first direction,
a sixth electrode position of the sixth electrode in the third direction being between a fourth electrode position of the fourth electrode in the third direction and a fifth electrode position of the fifth electrode in the third direction,
the second semiconductor region further including a fourth partial region, a fifth partial region, and a sixth partial region,
the fourth partial region being between the first semiconductor region and the fourth electrode in the first direction,
the fifth partial region being between the first semiconductor region and the fifth electrode in the first direction,
the sixth partial region being between the first semiconductor region and the sixth electrode in the first direction,
at least a part of the sixth electrode being between the fourth partial region and the fifth partial region in the third direction,
at least a part of the second insulating member being between the sixth electrode and the semiconductor member,
a <0001> direction of the first semiconductor region being along a second orientation from the first semiconductor region to the second semiconductor region.

### (Technical Proposal 7)

The semiconductor device according to Technical proposal 6, wherein
a <0001> direction of the second semiconductor region is along the second orientation, and
a <0001> direction of the third semiconductor region is along the second orientation.

### (Technical Proposal 8)

The semiconductor device according to Technical proposal 6 or 7, wherein
the fourth electrode is in contact with the fourth partial region, and
the fifth electrode is in contact with the fifth partial region.

### (Technical Proposal 9)

The semiconductor device according to any one of Technical proposals 6 to 8, wherein
a first current flowing between the first electrode and the second electrode is controlled by a first potential of the third electrode, and
a second current flowing between the fourth electrode and the fifth electrode is controlled by a second potential of the sixth electrode.

### (Technical Proposal 10)

The semiconductor device according to any one of Technical proposals 6 to 9, wherein
a first transistor including the first electrode, the second electrode, the third electrode, and the third semiconductor region is configured to perform a normally-off operation, and
a second transistor including the fourth electrode, the fifth electrode, the sixth electrode, the fourth partial region, the fifth partial region, and the sixth partial region is configured to perform a normally-off operation.

### (Technical Proposal 11)

The semiconductor device according to any one of Technical proposals 1 to 10, wherein
the first insulating member includes a first insulating region between the third partial region and the third electrode, and
the first insulating region is in contact with the third partial region and the third electrode.

### (Technical Proposal 12)

The semiconductor device according to any one of Technical proposals 1 to 10, wherein
the third semiconductor region further includes a third semiconductor portion,
the third semiconductor portion is between the third partial region and the third electrode in the first direction, and
a part of the first insulating member is between the third semiconductor portion and the third electrode.

### (Technical Proposal 13)

The semiconductor device according to Technical proposal 12, wherein a thickness of the third semiconductor portion in the first direction is more than 0 nm and 5 nm or less.

### (Technical Proposal 14)

The semiconductor device according to any one of Technical proposals 1 to 13, wherein
the first semiconductor region includes a first region and a second region,
the first partial region is between the first region and the first electrode in the first direction,
the second partial region is between the first region and the second electrode in the first direction,
the third partial region is between the first region and the third electrode in the first direction,
the fourth partial region is between the second region and the fourth electrode in the first direction,
the fifth partial region is between the second region and the fifth electrode in the first direction,
the sixth partial region is between the second region and the sixth electrode in the first direction, and
the first semiconductor region includes a recessed portion between the first region and the second region.

### (Technical Proposal 15)

The semiconductor device according to any one of Technical proposals 1 to 13, wherein
the first semiconductor region includes a first region and a second region,
the first partial region is between the first region and the first electrode in the first direction,
the second partial region is between the first region and the second electrode in the first direction,
the third partial region is between the first region and the third electrode in the first direction,
the fourth partial region is between the second region and the fourth electrode in the first direction,
the fifth partial region is between the second region and the fifth electrode in the first direction,
the sixth partial region is between the second region and the sixth electrode in the first direction,
the first semiconductor region further includes a first intermediate region between the first region and the second region, and
a first intermediate region electric resistance of the first intermediate region is higher than a first electric resistance of the first region and higher than a second electric resistance of the second region.

### (Technical Proposal 16)

A semiconductor device comprising:
a first electrode;
a second electrode;
a third electrode;
a fourth electrode;
a fifth electrode;
a sixth electrode;
a semiconductor member;
a first insulating member; and
a second insulating member,
the semiconductor member including
   a first semiconductor region including Alₓ₁Ga₁₋ₓ₁N (0<x1≤1),
   a second semiconductor region including Alₓ₂Ga₁₋ₓ₂N (0≤x2<1, x2<x1),
   a third semiconductor region including Alₓ₃Ga₁₋ₓ₃N (0<x3≤1), and
   a fourth semiconductor region including Alₓ₄Ga₁₋ₓ₄N (0≤x4<1, x4<x3),
a direction from the first semiconductor region to the first electrode, the second electrode, and the third electrode being along a first direction,
a second direction from the first electrode to the second electrode intersecting with the first direction,
a third electrode position of the third electrode in the second direction being between a first electrode position of the first electrode in the second direction and a second electrode position of the second electrode in the second direction,
the second semiconductor region including a first partial region and a second partial region,
the first partial region being between first semiconductor region and the first electrode in the first direction,
the second partial region being between the first semiconductor region and the second electrode in the first direction,
at least a part of the third electrode being between the first partial region and the second partial region in the second direction,
a <0001> direction of the first semiconductor region being along a first orientation from the first semiconductor region to the second semiconductor region,
at least a part of the first insulating member being between the third electrode and the semiconductor member,
a direction from the third semiconductor region to the fourth electrode, the fifth electrode, and the sixth electrode being along the first direction,
a third direction from the fourth electrode to the fifth electrode intersecting with the first direction,
a sixth electrode position of the sixth electrode in the third direction being between a fourth electrode position of the fourth electrode in the third direction and a fifth electrode position of the fifth electrode in the third direction,
the fourth semiconductor region including a fourth partial region and a fifth partial region,
the fourth partial region being between the third semiconductor region and the fourth electrode in the first direction,
the fifth partial region being between the third semiconductor region and the fifth electrode in the first direction,
at least a part of the sixth electrode being between the fourth partial region and the fifth partial region in the third direction,
a <0001> direction of the third semiconductor region being along a second orientation from the fourth semiconductor region to the third semiconductor region,
at least a part of the second insulating member being between the sixth electrode and the semiconductor member.

### (Technical Proposal 17)

The semiconductor device according to Technical proposal 16, wherein
the second semiconductor region further includes a third partial region,
the third partial region is between the first semiconductor region and the third electrode in the first direction,
a part of the first insulating member is between the third partial region and the third electrode,
the fourth semiconductor region further includes a sixth partial region,
the sixth partial region is between the third semiconductor region and the sixth electrode in the first direction, and
a part of the second insulating member is between the sixth partial region and the sixth electrode.

### (Technical Proposal 18)

The semiconductor device according to any one of Technical proposals 1 to 15, wherein
at least any of the first insulating member and the second insulating member includes oxygen and a first element, and
the first element includes at least one selected from the group consisting of Si, Al, and Hf.

### (Technical Proposal 19)

The semiconductor device according to any one of Technical proposals 1 to 18, wherein
the first semiconductor region does not include a p-type impurity, or
a concentration of the p-type impurity in the first semiconductor region is less than 1×10¹⁷ cm⁻³.

### (Technical Proposal 20)

The semiconductor device according to Technical proposal 19, wherein the p-type impurity includes at least one selected from the group consisting of Mg, Zn, and Be.

According to the embodiments, a semiconductor device capable of improving characteristics is provided.

In the specification, the “state of being electrically connected” includes a state in which a plurality of conductors are physically in contact with each other and a current flows between the plurality of conductors. The “state of being electrically connected” includes a state in which another conductor is inserted between the plurality of conductors and a current flows between the plurality of conductors.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in the semiconductor devices such as electrodes, semiconductor members, semiconductor regions, insulating members, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all semiconductor devices practicable by an appropriate design modification by one skilled in the art based on the semiconductor devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device comprising:
a first electrode;
a second electrode;
a third electrode;
a fourth electrode;
a fifth electrode;
a sixth electrode;
a semiconductor member;
a first insulating member; and
a second insulating member,
the semiconductor member including
a first semiconductor region including Alₓ₁Ga₁₋ₓ₁N (0<x1≤1),
a second semiconductor region including Alₓ₂Ga₁₋ₓ₂N (0≤x2<1, x2<x1), and
a third semiconductor region including Alₓ₃Ga₁₋ₓ₃N (0<x3≤1, x2<x3),
a direction from the first semiconductor region to the first electrode, the second electrode, the third electrode, the fourth electrode, the fifth electrode, and the sixth electrode being along a first direction,
a second direction from the first electrode to the second electrode intersecting with the first direction,
a third electrode position of the third electrode in the second direction being between a first electrode position of the first electrode in the second direction and a second electrode position of the second electrode in the second direction,
the second semiconductor region including a first partial region, a second partial region, and a third partial region,
the first partial region being between the first semiconductor region and the first electrode in the first direction,
the second partial region being between the first semiconductor region and the second electrode in the first direction,
the third partial region being between the first semiconductor region and the third electrode in the first direction,
the third semiconductor region including a first semiconductor portion and a second semiconductor portion,
the first semiconductor portion being between the first partial region and the first electrode,
the second semiconductor portion being between the second partial region and the second electrode,
at least a part of the third electrode being between the first semiconductor portion and the second semiconductor portion in the second direction,
at least a part of the first insulating member being between the third electrode and the semiconductor member,
a third direction from the fourth electrode to the fifth electrode intersecting with the first direction,
a sixth electrode position of the sixth electrode in the third direction being between a fourth electrode position of the fourth electrode in the third direction and a fifth electrode position of the fifth electrode in the third direction,
the second semiconductor region further including a fourth partial region, a fifth partial region, and a sixth partial region,
the fourth partial region being between the first semiconductor region and the fourth electrode in the first direction,
the fifth partial region being between the first semiconductor region and the fifth electrode in the first direction,
the sixth partial region being between the first semiconductor region and the sixth electrode in the first direction,
at least a part of the sixth electrode being between the fourth partial region and the fifth partial region in the third direction,
at least a part of the second insulating member being between the sixth electrode and the semiconductor member,
a <0001> direction of the first semiconductor region being along a first orientation from the second semiconductor region to the first semiconductor region.

2. The semiconductor device according to claim 1, wherein
a <0001> direction of the second semiconductor region is along the first orientation, and
a <0001> direction of the third semiconductor region is along the first orientation.

3. The semiconductor device according to claim 1, wherein
the fourth electrode is in contact with the fourth partial region, and
the fifth electrode is in contact with the fifth partial region.

4. The semiconductor device according to claim 1, wherein
a first current flowing between the first electrode and the second electrode is controlled by a first potential of the third electrode, and
a second current flowing between the fourth electrode and the fifth electrode is controlled by a second potential of the sixth electrode.

5. The semiconductor device according to claim 1, wherein
a first transistor including the first electrode, the second electrode, the third electrode, and the third semiconductor region is configured to perform a normally-off operation, and
a second transistor including the fourth electrode, the fifth electrode, the sixth electrode, the fourth partial region, the fifth partial region, and the sixth partial region is configured to perform a normally-off operation.

6. A semiconductor device comprising:
a first electrode;
a second electrode;
a third electrode;
a fourth electrode;
a fifth electrode;
a sixth electrode;
a semiconductor member;
a first insulating member; and
a second insulating member,
the semiconductor member including
a first semiconductor region including Alₓ₁Ga₁₋ₓ₁N (0<x1≤1),
a second semiconductor region including Alₓ₂Ga₁₋ₓ₂N (0≤x2<1, x2<x1), and
a third semiconductor region including Alₓ₃Ga₁₋ₓ₃N (0<x3≤1, x2<x3),
a direction from the first semiconductor region to the first electrode, the second electrode, the third electrode, the fourth electrode, the fifth electrode, and the sixth electrode being along a first direction,
a second direction from the first electrode to the second electrode intersecting with the first direction,
a third electrode position of the third electrode in the second direction being between a first electrode position of the first electrode in the second direction and a second electrode position of the second electrode in the second direction,
the second semiconductor region including a first partial region, a second partial region, and a third partial region,
the first partial region being between the first semiconductor region and the first electrode in the first direction,
the second partial region being between the first semiconductor region and the second electrode in the first direction,
the third partial region being between the first semiconductor region and the third electrode in the first direction,
the third semiconductor region including a first semiconductor portion and a second semiconductor portion,
the first semiconductor portion being between the first partial region and the first electrode,
the second semiconductor portion being between the second partial region and the second electrode,
at least a part of the third electrode being between the first semiconductor portion and the second semiconductor portion in the second direction,
at least a part of the first insulating member being between the third electrode and the semiconductor member,
a third direction from the fourth electrode to the fifth electrode intersecting with the first direction,
a sixth electrode position of the sixth electrode in the third direction being between a fourth electrode position of the fourth electrode in the third direction and a fifth electrode position of the fifth electrode in the third direction,
the second semiconductor region further including a fourth partial region, a fifth partial region, and a sixth partial region,
the fourth partial region being between the first semiconductor region and the fourth electrode in the first direction,
the fifth partial region being between the first semiconductor region and the fifth electrode in the first direction,
the sixth partial region being between the first semiconductor region and the sixth electrode in the first direction,
at least a part of the sixth electrode being between the fourth partial region and the fifth partial region in the third direction,
at least a part of the second insulating member being between the sixth electrode and the semiconductor member,
a <0001> direction of the first semiconductor region being along a second orientation from the first semiconductor region to the second semiconductor region.

7. The semiconductor device according to claim 6, wherein
a <0001> direction of the second semiconductor region is along the second orientation, and
a <0001> direction of the third semiconductor region is along the second orientation.

8. The semiconductor device according to claim 6, wherein
the fourth electrode is in contact with the fourth partial region, and
the fifth electrode is in contact with the fifth partial region.

9. The semiconductor device according to claim 6, wherein
a first current flowing between the first electrode and the second electrode is controlled by a first potential of the third electrode, and
a second current flowing between the fourth electrode and the fifth electrode is controlled by a second potential of the sixth electrode.

10. The semiconductor device according to claim 6, wherein
a first transistor including the first electrode, the second electrode, the third electrode, and the third semiconductor region is configured to perform a normally-off operation, and
a second transistor including the fourth electrode, the fifth electrode, the sixth electrode, the fourth partial region, the fifth partial region, and the sixth partial region is configured to perform a normally-off operation.

11. The semiconductor device according to claim 1, wherein
the first insulating member includes a first insulating region between the third partial region and the third electrode, and
the first insulating region is in contact with the third partial region and the third electrode.

12. The semiconductor device according to claim 1, wherein
the third semiconductor region further includes a third semiconductor portion,
the third semiconductor portion is between the third partial region and the third electrode in the first direction, and
a part of the first insulating member is between the third semiconductor portion and the third electrode.

13. The semiconductor device according to claim 12, wherein a thickness of the third semiconductor portion in the first direction is more than 0 nm and 5 nm or less.

14. The semiconductor device according to claim 1, wherein
the first semiconductor region includes a first region and a second region,
the first partial region is between the first region and the first electrode in the first direction,
the second partial region is between the first region and the second electrode in the first direction,
the third partial region is between the first region and the third electrode in the first direction,
the fourth partial region is between the second region and the fourth electrode in the first direction,
the fifth partial region is between the second region and the fifth electrode in the first direction,
the sixth partial region is between the second region and the sixth electrode in the first direction, and
the first semiconductor region includes a recessed portion between the first region and the second region.

15. The semiconductor device according to claim 1, wherein
the first semiconductor region includes a first region and a second region,
the first partial region is between the first region and the first electrode in the first direction,
the second partial region is between the first region and the second electrode in the first direction,
the third partial region is between the first region and the third electrode in the first direction,
the fourth partial region is between the second region and the fourth electrode in the first direction,
the fifth partial region is between the second region and the fifth electrode in the first direction,
the sixth partial region is between the second region and the sixth electrode in the first direction,
the first semiconductor region further includes a first intermediate region between the first region and the second region, and
a first intermediate region electric resistance of the first intermediate region is higher than a first electric resistance of the first region and higher than a second electric resistance of the second region.

16. A semiconductor device comprising:
a first electrode;
a second electrode;
a third electrode;
a fourth electrode;
a fifth electrode;
a sixth electrode;
a semiconductor member;
a first insulating member; and
a second insulating member,
the semiconductor member including
a first semiconductor region including Alₓ₁Ga₁₋ₓ₁N (0<x1≤1),
a second semiconductor region including Alₓ₂Ga₁₋ₓ₂N (0≤x2<1, x2<x1),
a third semiconductor region including Alₓ₃Ga₁₋ₓ₃N (0<x3≤1), and
a fourth semiconductor region including Alₓ₄Ga₁₋ₓ₄N (0≤x4<1, x4<x3),
a direction from the first semiconductor region to the first electrode, the second electrode, and the third electrode being along a first direction,
a second direction from the first electrode to the second electrode intersecting with the first direction,
a third electrode position of the third electrode in the second direction being between a first electrode position of the first electrode in the second direction and a second electrode position of the second electrode in the second direction,
the second semiconductor region including a first partial region and a second partial region,
the first partial region being between the first semiconductor region and the first electrode in the first direction,
the second partial region being between the first semiconductor region and the second electrode in the first direction,
at least a part of the third electrode being between the first partial region and the second partial region in the second direction,
a <0001> direction of the first semiconductor region being along a first orientation from the first semiconductor region to the second semiconductor region,
at least a part of the first insulating member being between the third electrode and the semiconductor member,
a direction from the third semiconductor region to the fourth electrode, the fifth electrode, and the sixth electrode being along the first direction,
a third direction from the fourth electrode to the fifth electrode intersecting with the first direction,
a sixth electrode position of the sixth electrode in the third direction being between a fourth electrode position of the fourth electrode in the third direction and a fifth electrode position of the fifth electrode in the third direction,
the fourth semiconductor region including a fourth partial region and a fifth partial region,
the fourth partial region being between the third semiconductor region and the fourth electrode in the first direction,
the fifth partial region being between the third semiconductor region and the fifth electrode in the first direction,
at least a part of the sixth electrode being between the fourth partial region and the fifth partial region in the third direction,
a <0001> direction of the third semiconductor region being along a second orientation from the fourth semiconductor region to the third semiconductor region,
at least a part of the second insulating member being between the sixth electrode and the semiconductor member.

17. The semiconductor device according to claim 16, wherein
the second semiconductor region further includes a third partial region,
the third partial region is between the first semiconductor region and the third electrode in the first direction,
a part of the first insulating member is between the third partial region and the third electrode,
the fourth semiconductor region further includes a sixth partial region,
the sixth partial region is between the third semiconductor region and the sixth electrode in the first direction, and
a part of the second insulating member is between the sixth partial region and the sixth electrode.

18. The semiconductor device according to claim 1, wherein
at least any of the first insulating member and the second insulating member includes oxygen and a first element, and
the first element includes at least one selected from the group consisting of Si, Al, and Hf.

19. The semiconductor device according to claim 1, wherein
the first semiconductor region does not include a p-type impurity, or
a concentration of the p-type impurity in the first semiconductor region is less than 1×10¹⁷ cm⁻³.

20. The semiconductor device according to claim 19, wherein the p-type impurity includes at least one selected from the group consisting of Mg, Zn, and Be.
